(19) United States
(12) Patent Application Publication
(10) Pub. No.: US 2025/0349576 A1
(43) Pub. Date: Nov. 13, 2025

(54) APPARATUS FOR TREATING SUBSTRATE

(71) Applicant: SEMES CO., LTD., Cheonan-si (KR)

(72) Inventors: Do Hyeon YOON, Cheonan-si (KR); Eun Seok KIM, Asan-si (KR)

(73) Assignee: SEMES CO., LTD., Cheonan-si (KR)

(21) Appl. No.: 19/202,369

(22) Filed: May 8, 2025

(30) Foreign Application Priority Data
May 10, 2024 (KR) 10-2024-0061570

(51) Int. Cl. H01L 21/67; B08B 3/08; B08B 13/00; F26B 3/02

(52) U.S. Cl. CPC H01L 21/67248; B08B 3/08; B08B 13/00; F26B 3/02; H01L 21/67051

(57) ABSTRACT

Disclosed are a substrate treating apparatus and a substrate treating method of treating a substrate. An apparatus for treating a substrate, the apparatus comprising: a housing having a treatment space in which a substrate is placed; a fluid supply unit for supplying a drying fluid to the treatment space; and an exhaust unit for exhausting an exhaust fluid from the treatment space, wherein the exhaust fluid includes at least one of the drying fluid and a cleaning fluid supplied onto the substrate and introduced into the treatment space, wherein the exhaust unit includes: an exhaust line connected with the housing; and a monitoring member installed on the exhaust line, wherein the monitoring member may include a buoy having a density between a density of the drying fluid and a density of the cleaning fluid.

### CROSS-REFERENCE TO RELATED APPLICATIONS

This application claims priority to and the benefit of Korean Patent Application No. 10-2024-0061570 filed in the Korean Intellectual Prope Office on May 10, 2024, the entire contents of which are incorporated herein by reference.

### TECHNICAL FIELD

The present invention relates to a substrate treating apparatus.

### BACKGROUND ART

In general, a semiconductor device is manufactured from a substrate, such as a wafer. Specifically, the semiconductor device is manufactured by forming a fine circuit pattern on an upper surface of the substrate by performing a deposition process, a photolithography process, an etching process, and the like.

Since various foreign substances are attached to the upper surface of the substrate on which the circuit pattern is formed while performing the above processes, a cleaning process for removing foreign substances on the substrate is performed between the processes.

In general, the cleaning process includes chemical treatment of removing foreign substances on a substrate by supplying a chemical to the substrate, rinsing treatment of removing the chemicals left on the substrate by supplying deionized water to the substrate, and drying treatment of removing the deionized water left on the substrate.

A supercritical fluid is used for the drying treatment of the substrate. For example, the pure water on the substrate is replaced with an organic solvent, and then supercritical fluid is supplied to the top surface of the substrate in a high-pressure chamber to dissolve the organic solvent remaining on the substrate in the supercritical fluid and remove the organic solvent from the substrate. When isopropyl alcohol (hereinafter, referred to as “IPA”) is used as the organic solvent, carbon dioxide (CO₂) which has a relatively low critical temperature and critical pressure and in which IPA is well soluble is used as the supercritical fluid.

The treatment of the substrate by using the supercritical fluid is as follow. When the substrate is loaded into the high-pressure chamber, carbon dioxide in a supercritical state is supplied into the high-pressure chamber to pressurize the inside of the high-pressure chamber, and thereafter, the substrate is treated with the supercritical fluid while repeating the supply of the supercritical fluid and the exhaust of the high-pressure chamber. Then, when the treatment of the substrate is completed, the pressure is reduced by exhausting the inside of the high-pressure chamber.

In a conventional supercritical substrate drying process, a low-density supercritical fluid is supplied at a high temperature of 100° C. or higher to dry the IPA on the substrate. In this case, the low-density supercritical fluid behaves unidirectionally from top to bottom in the chamber where the supercritical process is performed. The IPA that is not dissolved in the supercritical fluid existing the chamber due to the upward and downward flow is retained and adsorbed on the substrate, causing pattern leaning phenomenon or particles. If the process time is increased to reduce the amount of IPA remaining on the substrate, there is a problem in that the cost of the semiconductor increases and the yield decreases.

### SUMMARY OF THE INVENTION

The present invention has been made in an effort to provide a substrate treating apparatus capable of improving the treating efficiency of a substrate when treating the substrate by using a supercritical fluid.

The present invention has also been made in an effort to provide a substrate treating apparatus capable of monitoring a drying process performed on a substrate by using a supercritical fluid.

The objectives of the present disclosure are not limited thereto and other objectives not stated herein may be clearly understood by those skilled in the art from the following description.

An exemplary embodiment of the present invention, an apparatus for treating a substrate, the apparatus comprising: a housing having a treatment space in which a substrate is placed; a fluid supply unit for supplying a drying fluid to the treatment space; and an exhaust unit for exhausting an exhaust fluid from the treatment space, wherein the exhaust fluid includes at least one of the drying fluid and a cleaning fluid supplied onto the substrate and introduced into the treatment space, wherein the exhaust unit includes: an exhaust line connected with the housing; and a monitoring member installed on the exhaust line, wherein the monitoring member may include a buoy having a density between a density of the drying fluid and a density of the cleaning fluid.

According to the embodiment of the present invention, the drying fluid may include carbon dioxide, and the cleaning fluid includes isopropyl alcohol (IPA).

According to the embodiment of the present invention, the exhaust unit may include: a temperature sensor installed on the exhaust line and for measuring a temperature of the drying fluid flowing in the exhaust line; and a pressure sensor installed on the exhaust line and for measuring a pressure of the drying fluid flowing in the exhaust line.

According to the embodiment of the present invention, the monitoring member may be installed between the temperature sensor and the pressure sensor.

According to the embodiment of the present invention, the monitoring member may include: a bracket connected to the exhaust line to form a hole therein; and a cover enclosing the hole.

According to the embodiment of the present invention, the cover may be provide as a window.

According to the embodiment of the present invention, the buoy may be provide to the hole.

According to the embodiment of the present invention, the exhaust fluid may be a supercritical fluid.

An exemplary embodiment of the present invention, an apparatus for treating a substrate, the apparatus comprising: a housing having a treatment space in which a substrate is placed; a fluid supply unit for supplying a drying fluid to the treatment space; and an exhaust unit for exhausting an exhaust fluid from the treatment space, wherein the exhaust fluid includes at least one of the drying fluid and a cleaning fluid supplied onto the substrate and introduced into the treatment space, the exhaust unit includes: an exhaust line connected with the housing; and a monitoring member installed on the exhaust line, and a monitoring member may include a first buoy having a density between a density of the drying fluid and a density of the cleaning fluid, and a second buoy having a density greater than the density of the cleaning fluid.

According to the embodiment of the present invention, the drying fluid includes carbon dioxide, and the cleaning fluid may include isopropyl alcohol (IPA).

According to the embodiment of the present invention, the exhaust unit includes: a temperature sensor installed on the exhaust line and for measuring a temperature of the drying fluid flowing in the exhaust line; and a pressure sensor installed on the exhaust line and for measuring a pressure of the drying fluid flowing in the exhaust line, wherein the monitoring member may be install between the temperature sensor and the pressure sensor.

According to the embodiment of the present invention, the monitoring member includes: a bracket connected to the exhaust line to form a hole therein; and a cover enclosing the hole, and the cover may be provide as a window.

According to the embodiment of the present invention, the first buoy and the second buoy may be provide to the hall.

According to the embodiment of the present invention, the exhaust fluid may be a supercritical fluid.

According to the embodiment of the present invention, the housing may be a drying chamber.

An exemplary embodiment of the present invention, an apparatus for treating a substrate, the apparatus comprising: a housing having a treatment space in which a substrate is placed; a fluid supply unit for supplying a drying fluid to the treatment space; and an exhaust unit for exhausting an exhaust fluid from the treatment space, wherein the exhaust fluid includes at least one of the drying fluid and a cleaning fluid supplied onto the substrate and introduced into the treatment space, the exhaust unit includes: an exhaust line connected with the housing; a temperature sensor installed on the exhaust line and for measuring a temperature of the dry fluid flowing in the exhaust line; a pressure sensor installed on the exhaust line and for measuring a pressure of the drying fluid flowing in the exhaust line; and a monitoring member installed between the temperature sensor and the pressure sensor, wherein the monitoring member may include a first buoy having a density between a density of the drying fluid and a density of the cleaning fluid.

According to the embodiment of the present invention, the drying fluid includes carbon dioxide, and the cleaning fluid may include isopropyl alcohol (IPA).

According to the embodiment of the present invention, the monitoring member further may include a second buoy having a density greater than the density of the cleaning fluid.

According to the embodiment of the present invention, the monitoring member includes:

a bracket connected to the exhaust line to form a hole therein; and a cover enclosing the hole, and the cover is provided as a window, and the first buoy may be provide to the hole.

According to the embodiment of the present invention, the exhaust fluid may be a supercritical fluid.

According to the embodiment of the present invention, the drying efficiency of the substrate may be improved when the substrate is dried using a supercritical fluid.

According to the embodiment of the present invention, optimization of the drying process may be achieved by monitoring the drying process of the substrate using the supercritical fluid as it is being carried out.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a top plan view schematically illustrating a substrate treating apparatus according to an exemplary embodiment of the present invention.

FIG. 2 is a diagram schematically illustrating an exemplary embodiment of a liquid treating chamber of FIG. 1.

FIG. 3 is a diagram schematically illustrating an exemplary embodiment of the drying chamber of FIG. 1.

FIG. 4 is a drawing schematically illustrating an exhaust unit according to the embodiment of the present invention.

FIG. 5 is an enlarged view of portion “A” of FIG. 4.

FIGS. 6 and 7 are diagrams illustrating a monitoring member according to the embodiment of the present invention.

FIG. 8 is a diagram illustrating a monitoring member according to another embodiment of the present invention.

FIGS. 9 and 10 are diagrams illustrating a monitoring member according to another embodiment of the present invention.

### DETAILED DESCRIPTION

Hereinafter, an exemplary embodiment of the present invention will be described in more detail with reference to the accompanying drawings. The exemplary embodiment of the present invention may be modified in various forms, and the scope of the present invention should not be construed as being limited to the following exemplary embodiments. This exemplary embodiment is provided to more completely explain the present invention to those of ordinary skill in the art. Therefore, the shapes of elements in the drawings are exaggerated to emphasize a clearer description.

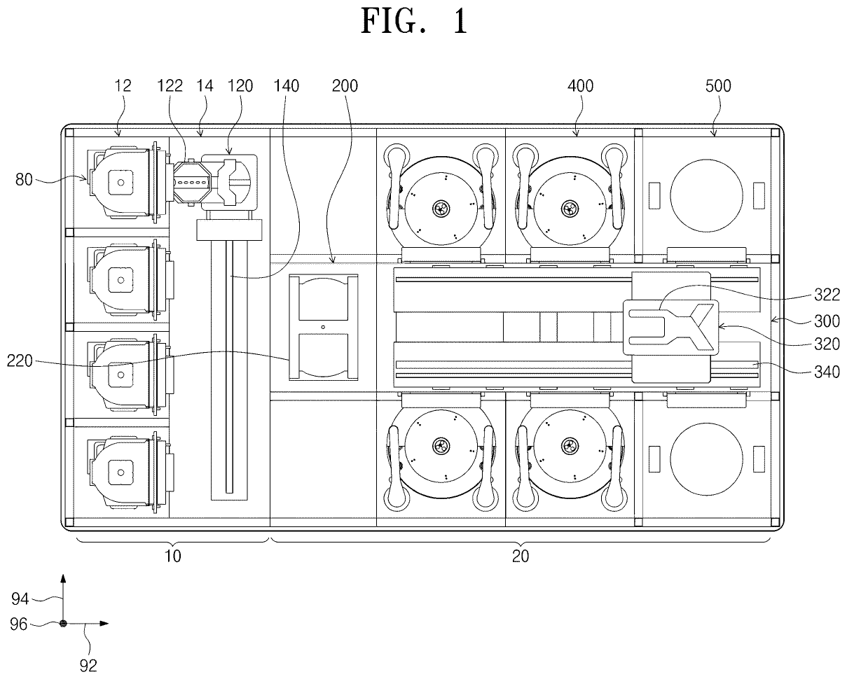

FIG. 1 is a top plan view schematically illustrating a substrate treating apparatus according to an exemplary embodiment of the present invention. Referring to FIG. 1, the substrate treating system includes an index module 10, a treating module 20, and a controller (not illustrated). According to the embodiment, the index module 10 and the treating module 20 are disposed along one direction. Hereinafter, the direction in which the index module 10 and the treating module 20 are disposed is referred to as a first direction 92, and when viewed from above, a direction vertical to the first direction 92 is referred to as a second direction 94, and a direction perpendicular to both the first direction 92 and the second direction 94 is referred to as a third direction 96.

The index module 10 transfers a substrate W from a container 80 in which the substrate W is accommodated to the treating module 20, and makes the substrate W, which has been completely treated in the treating module 20, be accommodated in the container 80. A longitudinal direction of the index module 10 is provided in the second direction 94. The index module 10 includes a load port 12 (load port) and an index frame 14. Based on the index frame 14, the load port 12 is located at a side opposite to the treating module 20. The containers 80 in which the substrates W are accommodated are placed on the load ports 12. The load port 12 may be provided in plurality, and the plurality of load ports 12 may be disposed in the second direction 94.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

An index robot 120 is provided to the index frame 14. A guide rail 140 of which a longitudinal is the second direction 94 is provided within the index frame 14, and the index robot 120 may be provided to be movable on the guide rail 140. The indexing robot 120 includes a hand 122 on which the substrate W is placed, and the hand 122 may be provided to be movable forward and backward, rotatable about the third direction 96, and movable along the third direction 96. The plurality of hands 122 is provided while being spaced apart from each other in the vertical direction, and is capable of independently moving forward and backward.

The treating module 20 includes a buffer unit 200, a transfer unit 300, a liquid treating chamber 400, and a drying chamber 500. The buffer unit 200 provides a space in which the substrate W loaded into the treating module 20 and the substrate W unloaded from the treating module 20 stay temporarily. The liquid treating chamber 400 performs a liquid treating process of treating the substrate W with a liquid by supplying a liquid onto the substrate W. The drying chamber 500 performs a drying process of removing the liquid residual on the substrate W. The transfer device 300 transfers the substrate W between the buffer unit 200, the liquid treating chamber 400, and the drying chamber 500.

A longitudinal direction of the transfer device 300 may be the first direction 92. The buffer unit 200 may be disposed between the index module 10 and the transfer device 300. The liquid treating chamber 400 and the drying chamber 500 may be disposed at a side portion of the transfer device 300. The liquid treating chamber 400 and the transfer device 300 may be disposed along the second direction 94. The drying chamber 500 and the transfer device 300 may be disposed along the second direction 94. The buffer unit 200 may be positioned at one end of the transfer device 300.

For example, the liquid treating chambers 400 are disposed on opposite sides of the transfer device 300 and the drying chambers 500 are disposed on opposite sides of the transfer device 300, and the liquid treating chambers 400 may be disposed closer to the buffer unit 200 than the drying chambers 500. At one side of the transfer device 300, the liquid treating chambers 400 may be provided in an arrangement of A×B (each of A and B is 1 or a natural larger than 1) in the first direction 92 and the third direction 96. Further, at one side of the transfer device 300, the drying chambers 500 may be provided in number of C×D (each of C and D is 1 or a natural number larger than 1) in the first direction 92 and the third direction 96. As described above, one side of the transfer device 300 may be provided with only liquid treating chambers 400 and the other side may be provided with only drying chambers 500.

The transfer device 300 includes a transfer robot 320. A guide rail 340, of which a longitudinal direction is the first direction 92, is provided within the transfer device 300, and the transfer robot 320 may be provided to be movable on the guide rail 340. The transfer robot 320 includes a hand 322 in which the substrate W is placed, and the hand 322 may be provided to be movable forwardly and backwardly, rotatable about the third direction 96, and movable along the third direction 96. The plurality of hands 322 is provided while being spaced apart from each other in the vertical direction, and is capable of independently moving forwardly and backwardly.

The buffer unit 200 includes a plurality of buffers 220 on which the substrate W is placed. The buffers 220 may be disposed while being spaced apart from each other in the third direction 96. A front face and a rear face of the buffer unit 200 are opened. The front face is the face facing the index module 10, and the rear face is the face facing the transfer device 300. The index robot 120 may approach the buffer unit 200 through the front face, and the transfer robot 320 may approach the buffer unit 200 through the rear face.

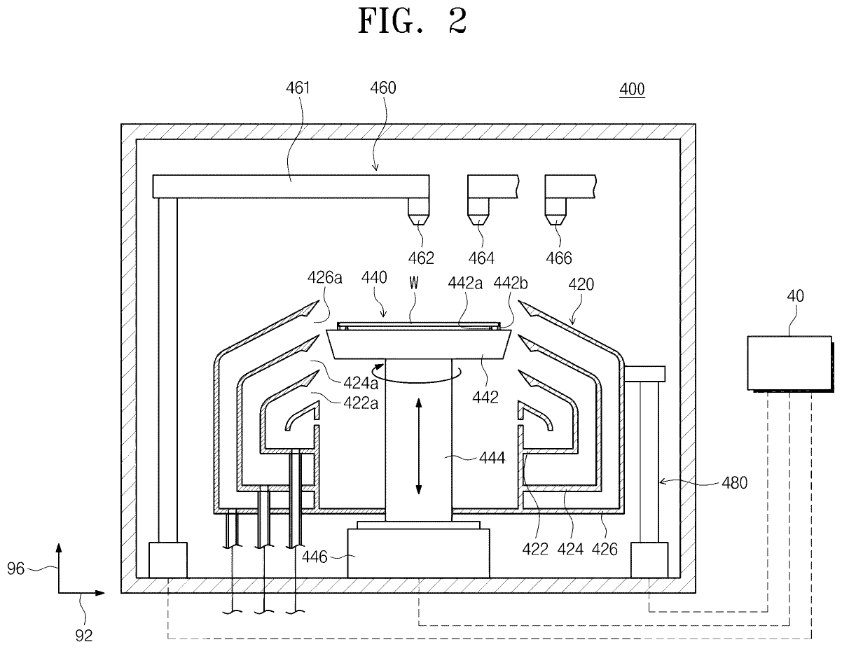

FIG. 2 is a diagram schematically illustrating an exemplary embodiment of the liquid treating chamber 400 of FIG. 1. Referring to FIG. 2, the liquid treating chamber 400 includes a housing 410, a cup 420, a support unit 440, a liquid supply unit 460, a lifting unit 480, and a controller 40. The control unit 40 controls the operations of the liquid supply unit 460, the support unit 440, and the lifting unit 480. The housing 410 is provided in a generally rectangular parallelepiped shape. The cup 420, the support unit 440, and the liquid supply unit 460 are disposed in the housing 410.

The cup 420 has a treatment space having an open top, and the substrate W is liquid- treated within the treatment space. The support unit 440 supports the substrate W within the treatment space. The liquid supply unit 460 supplies the liquid onto the substrate W supported by the support unit 440. Herein, the liquid may be a cleaning fluid. The liquid may be provided in a plurality of types, and may be sequentially supplied onto the substrate W. The lifting unit 480 adjusts a relative height between the cup 420 and the support unit 440.

For example, the cup 420 includes a plurality of recovery containers 422, 424, and 426. Each of the recovery containers 422, 424, and 426 has a recovery space of recovering the liquid used for the treatment of the substrate. Each of the recovery containers 422, 424, and 426 is provided in a ring shape surrounding the support unit 440. The pre-treatment liquid scattered by the rotation of the substrate W when the liquid treatment process progresses is introduced into the recovery space through inlets 422a, 424a, and 426a of the recovery containers 422, 424, and 426, respectively. For example, the cup 420 includes a first recovery container 422, a second recovery container 424, and a third recovery container 426. The first recovery container 422 is disposed to surround the support unit 440, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 440 includes a support plate 442 and a driving shaft 444. An upper surface of the support plate 442 may be provided in a generally circular shape, and may have a diameter larger than a diameter of the substrate W. In the center portion of the support plate 442, a support pin 442a is provided to support the rear surface of the substrate W, and the support pin 442a is provided with its upper end protruding from the support plate 442 so that the substrate W is spaced apart from the support plate 442 by a certain distance. A chuck pin 442b is provided to an edge of the support plate 442.

The chuck pin 442b is provided to protrude upward from the support plate 442, and supports the lateral portion of the substrate W so that the substrate W is not separated from the support unit 440 when the substrate W is rotated. A drive shaft 444 is driven by a driver 446, is connected to the center of the bottom surface of the substrate W, and rotates the support plate 442 with respect to the central axis thereof.

For example, the liquid supply unit 460 includes a first nozzle 462, a second nozzle 464, and a third nozzle 466. The first nozzle 462 supplies a first liquid onto the substrate W. The first liquid may be the liquid of removing a film or foreign substances residual on the substrate W. The second nozzle 464 supplies the second liquid onto the substrate W. The second liquid may be the liquid well soluble in a third liquid. For example, the second liquid may be the liquid that is better soluble in the third liquid than the first liquid. The second liquid may be the liquid that neutralizes the first liquid supplied onto the substrate W. Further, the second liquid may be the liquid that neutralizes the first liquid and at the same time is better soluble in the third liquid than the first liquid.

For example, the second liquid may be water. The third nozzle 466 supplies a third liquid onto the substrate W. The third liquid may be a liquid that is well soluble in the supercritical fluid used in the drying chamber 500. For example, the third liquid may be a liquid that is more soluble in the supercritical fluid used in the drying chamber 500 than the second liquid. For example, the third liquid may be an organic solvent. The organic solvent may be isopropyl alcohol (IPA). For example, the supercritical fluid may be carbon dioxide.

The first nozzle 462, the second nozzle 464, and the third nozzle 466 are supported on different arms 461, and the arms 461 may be moved independently. Optionally, the first nozzle 462, the second nozzle 464, and the third nozzle 466 may be mounted to the same arm and moved at the same time.

The lifting unit 480 moves the cup 420 in the up and down direction. By the up and down movement of the cup 420, a relative height between the cup 420 and the substrate W is changed. Accordingly, since the recovery containers 422, 424, and 426 for recovering the pre- treatment liquid are changed according to the type of the liquid supplied to the substrate W, the liquids may be separated and recovered. Unlike the description, the cup 420 may be fixedly installed, and the lifting unit 480 may move the support unit 440 in the vertical direction.

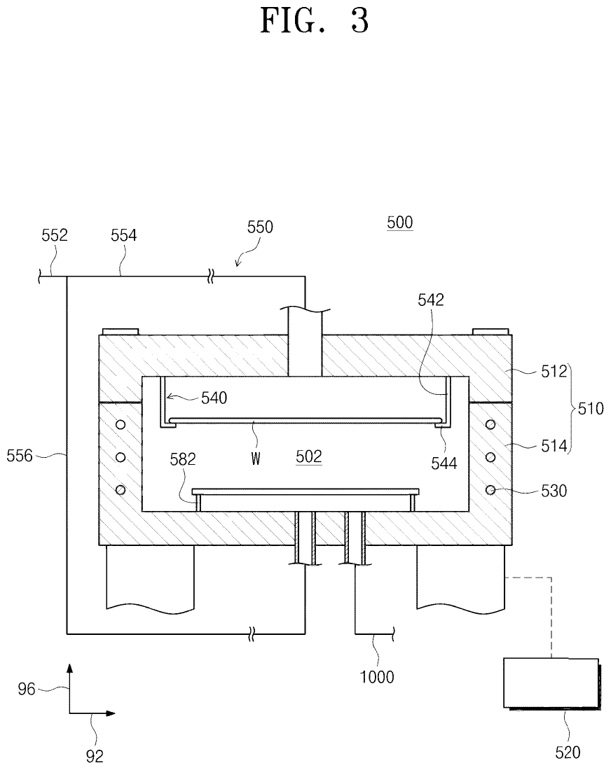

FIG. 3 is a diagram schematically illustrating a supercritical device of the drying chamber of FIG. 1 according to the embodiment.

The drying chamber 500 may provide drying fluid to the substrate W that has been liquid-treated by the cleaning fluid in the liquid treatment chamber 400 to dry-treat the substrate W. According to the embodiment, the cleaning fluid may include isopropyl alcohol (IPA). According to the embodiment, the drying fluid may be a supercritical fluid SCF, and the drying chamber 500 may remove the cleaning fluid from the substrate W by using a supercritical fluid SCF, which may be carbon dioxide in a supercritical state.

The drying chamber 500 may include a housing 510, a drive unit 520, a heater 530, a support unit 540, a fluid supply unit 550, and an exhaust unit 1000.

The housing 510 may provide a treatment space 502 in which the drying process is performed. The housing 510 may include an upper housing 512 and a lower housing 514. The upper housing 512 and the lower housing 514 may be combined with each other to provide the treatment space 502 described above. The upper housing 512 may be provided on top of the lower housing 514. The upper housing 512 may be fixed in position.

The drive unit 520 may raise and lower the lower housing 514. For example, the drive unit 520 may be a cylinder. When the lower housing 514 is spaced apart from the upper housing 512, the treatment space 502 may open, and the substrate W may be loaded or unloaded. During the process, the lower housing 514 and the upper housing 512 are in close contact with each other, so that the treatment space 502 may be sealed from the outside.

The heater 530 may be located inside a wall of the housing 510. The heater 530 may heat the treatment space 502 of the housing 510 such that the supercritical fluid SCF supplied into the treatment space 502 of the housing 510 remains in a supercritical state.

The support unit 540 may support the substrate W within the treatment space 502 of the housing 510. The support unit 540 may include a fixing rod 542 and a holder 544.

The fixing rod 542 may be fixedly installed in the upper housing 512 such that it protrudes downwardly from a bottom surface of the upper housing 512. The fixing rod 542 is provided so that a longitudinal direction thereof is the up and down direction. The fixing rods 542 may be provided in plurality and may be spaced apart from each other. The fixing rods 542 may be arranged such that when the substrate W is loaded into or unloaded from the space surrounded by the fixing rods 542, the substrate W does not interfere with the fixing rods 542. Each of the fixing rods 542 may be coupled to the holder 544.

The holder 544 may extend from the lower ends of the fixing rods 542 in a direction toward the space surrounded by the fixing rods 542. Due to the above-described structure, the substrate W loaded into the treatment space 502 of the housing 520 has an edge region placed on the holder 544, and the entire upper surface region of the substrate W, the center region of the bottom surface of the substrate W, and a portion of the edge region of the bottom surface of the substrate W are exposed to the supercritical fluid SCF supplied to the treatment space 502.

The fluid supply unit 550 may supply a supercritical fluid SCF to the treatment space 502 of the housing 510. In one example, the supercritical fluid SCF may be supplied to the treatment space 502 in a supercritical state. Alternatively, the supercritical fluid SCF may be supplied to the treatment space 502 in a gaseous state and phase-change to the supercritical state within the treatment space 502.

The fluid supply unit 550 may include a main supply line 552, an upper branch line 554, and a lower branch line 556.

The upper branch line 554 and the lower branch line 556 may branch from the main supply line 552. The upper branch line 554 may be coupled to the upper housing 512 to supply the supercritical fluid SCF to an upper portion of the substrate W placed on the support unit 540.

For example, the upper branch line 554 may be coupled to the center of the upper housing 512.

The lower branch line 556 may be coupled to the lower housing 514 to supply the supercritical fluid from the lower portion of the substrate W placed on the support unit 540. For example, the lower branch line 556 may be coupled to the center of the lower housing 514.

The exhaust unit 1000 may exhaust the exhaust fluid from the treatment space 502 to the outside. The exhaust fluid may include at least one of the drying fluid and a cleaning fluid supplied onto the substrate and introduced into the treatment space. For example, when a drying process is being performed on the substrate W in the treatment space 502, the exhaust fluid may include the drying fluid and the cleaning fluid, and when the drying process on the substrate W is complete, the exhaust fluid may include the drying fluid. The exhaust fluid may be a supercritical fluid.

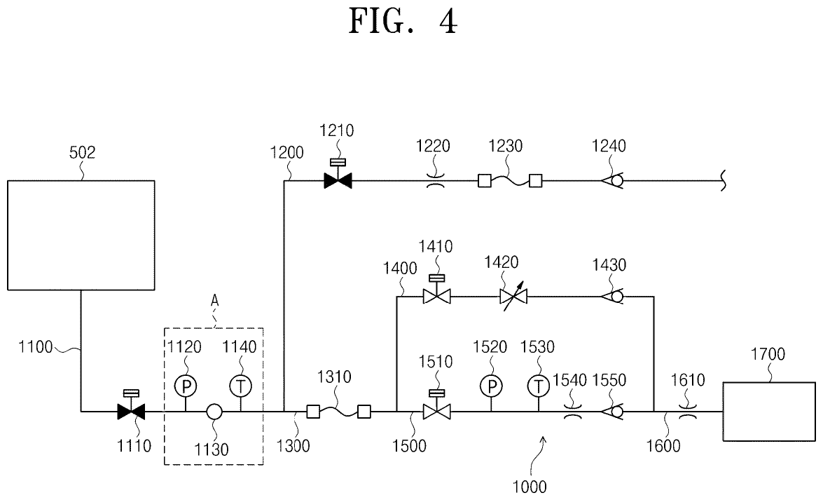

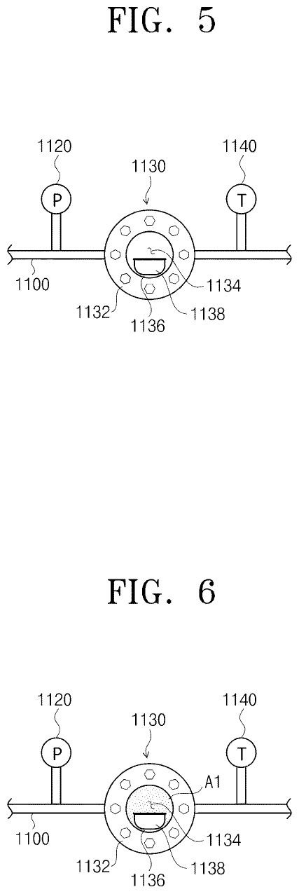

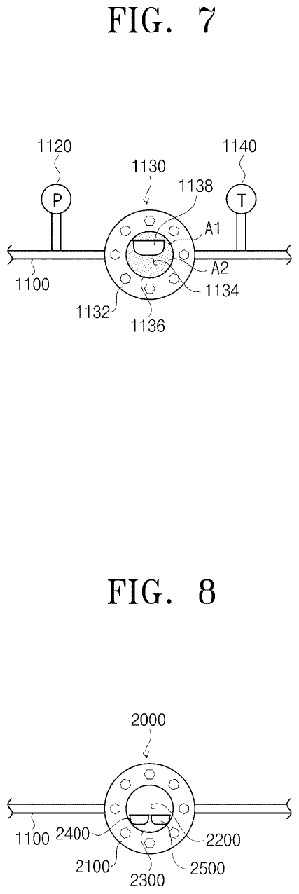

FIG. 4 is a drawing schematically illustrating the exhaust unit according to the embodiment of the present invention. FIG. 5 is an enlarged view of portion “A” of FIG. 4. FIGS. 6 and 7 are diagrams illustrating a monitoring member according to the embodiment of the present invention.

Referring now to FIGS. 4 and 5, the exhaust unit 1000 according to the embodiment of the present invention may include a first exhaust line 1100, a second exhaust line 1200, a third exhaust line 1300, a fourth exhaust line 1400, a fifth exhaust line 1500, a sixth exhaust line 1600, and an exhaust manifold 1700.

The first exhaust line 1100 may be coupled to the lower housing 514. One end of the first exhaust line 110 may communicate with the treatment space 502. The exhaust fluid from the treatment space 502 may flow in the first exhaust line 1100. The exhaust fluid may flow from one end of the first exhaust line 1100 to the other end.

In the first exhaust line 1100, there may be installed a first valve 1110, a pressure sensor 1120, a monitoring member 1130, and a temperature sensor 1140.

The first valve 1110 may be installed upstream of the first exhaust line 1100. The first valve 1110 may be an on/off valve. When the first valve 1110 is open, the exhaust fluid may flow in the first exhaust line 1100, and when the first valve 1110 is closed, the exhaust fluid may not flow in the first exhaust line 110.

The pressure sensor 1120 may be installed downstream of the first valve 1110. The pressure sensor 1122 may measure the pressure of the exhaust fluid flowing in the first exhaust line 1100.

The monitoring member 1130 may be installed downstream of the pressure sensor 1120. The monitoring member 1130 may include a bracket 1132 that is connected to the first exhaust line 1100 and forms a hole 1134 therein, a cover 1136 that surrounds the hole 1134, and a buoy 1138 provided in the hole 1134. Here, the cover 1136 may be a window, and the buoy 1138 may have a density between the density of the drying fluid and the density of the cleaning fluid. As the cover 1136 is provided as a window, the flow of the exhaust fluid flowing inside the hole 1134 and the buoy 1138 may be monitored.

Referring to FIG. 5, when the exhaust fluid containing only the drying fluid flows through the first exhaust line 1100 (i.e., when only the drying fluid flows through the hole 1134), the buoy 1138 having a density greater than the density of the drying fluid may sink.

Referring to FIG. 6, when the exhaust fluid containing a drying fluid A1 and a cleaning fluid A2 flows through the first exhaust line 1100 (i.e., the drying fluid A1 flows in the upper portion of the hole 1134 and the cleaning fluid A2 flows in the lower portion), the buoy 1138 having a density between the density of the drying fluid A1 and the density of the cleaning fluid A2 may float on the cleaning fluid A2.

Referring again to FIG. 4, a temperature sensor 1140 may be installed downstream of the monitoring member 1130. The temperature sensor 1140 may measure the temperature of the exhaust fluid flowing through the first exhaust line 1100.

The exhaust fluid entering the first exhaust line 1100 from the treatment space 502 may flow into the second exhaust line 1200 and the third exhaust line 1300.

The second exhaust line 1200 and the third exhaust line 1300 may branch off from the bottom of the first exhaust line 1100. The second exhaust line 1200 and the third exhaust line 1300 may receive the exhaust fluid from the first exhaust line 1200.

The second exhaust line 1200 may have a first valve 1210, a blocking member 1220, a pressure regulating member 1230, and a pump 1240.

The first valve 1210 may be installed upstream of the second exhaust line 1200. The first valve 1110 may be an on/off valve. When the first valve 1210 is open, the exhaust fluid may flow in the second exhaust line 1200, and when the first valve 1210 is closed, the exhaust fluid may not flow in the second exhaust line 1200.

The blocking member 1220 may be installed downstream of the first valve 1210. The blocking member 1220 may block the exhaust fluid from flowing in the second exhaust line 1200 based on a preset condition. For example, the blocking member 1220 may be bimetallic and may block the exhaust fluid from flowing in the second exhaust line 1200 when the temperature of the exhaust fluid is equal to or greater than a preset value.

The pressure regulating member 1230 may be installed downstream of the blocking member 1220. The pressure regulating member 1230 may regulate the pressure of the exhaust fluid flowing through the second exhaust line 1200. For example, the pressure regulating member 1230 may be an orifice and may depressurize the pressure of the exhaust fluid flowing in the second exhaust line 1200.

The pump 1240 may be installed downstream of the pressure regulating member 1230. The pump 1240 may provide exhaust pressure to the second exhaust line 1200.

The exhaust fluid introduced into the second exhaust line 1200 from the first exhaust line 1100 may be discharged to the outside.

A pressure regulating member 1310 may be installed in the third exhaust line 1300. The pressure regulating member 1310 may regulate the pressure of the exhaust fluid flowing through the third exhaust line 1300.

The exhaust fluid introduced into the third exhaust line 1300 from the first exhaust line 1100 may flow into the fourth exhaust line 1400 and the fifth exhaust line 1500.

The fourth exhaust line 1400 and the fifth exhaust line 1500 may branch off from the bottom end of the third exhaust line 1300. The fourth exhaust line 1500 and the fifth exhaust line 1500 may receive the exhaust fluid from the first exhaust line 1200.

The fourth exhaust line 1400 may include a first valve 1410, a second valve 1420, and a pump 1430.

The first valve 1410 may be installed upstream of the fourth exhaust line 1400. When the first valve 1410 is open, the exhaust fluid may flow in the fourth exhaust line 1400, and when the first valve 1410 is closed, the exhaust fluid may not flow in the fourth exhaust line 1400.

The second valve 1420 may be installed downstream of the first valve 1410. The second valve 1420 may be a needle valve and may regulate the flow rate of the exhaust fluid flowing through the fourth exhaust line 1400.

The pump 1430 may be installed downstream of the second valve 1420. The pump 1430 may provide exhaust pressure to the fourth exhaust line 1400.

The exhaust fluid introduced into the fourth exhaust line 1400 from the third exhaust line 1300 may flow into the sixth exhaust line 1600.

The fifth exhaust line 1500 may include a first valve 1510, a pressure sensor 1520, a temperature sensor 1530, a blocking member 1540, and a pump 1550.

The first valve 1510 may be installed upstream of the fifth exhaust line 1500. When the first valve 1510 is open, the exhaust fluid may flow in the fifth exhaust line 1500, and when the first valve 1510 is closed, the exhaust fluid may not flow in the fifth exhaust line 1500.

The pressure sensor 1520 may be installed downstream of the first valve 1520. The pressure sensor 1520 may measure the pressure of the exhaust fluid flowing through the fifth exhaust line 1500.

The temperature sensor 1530 may be installed downstream of the pressure sensor 1520. The temperature sensor 1530 may measure the temperature of the exhaust fluid flowing through the fifth exhaust line 1500.

The blocking member 1540 may be installed downstream of the temperature sensor 1530. The blocking member 1540 may block the exhaust fluid from flowing in the fifth exhaust line 1500 based on preset conditions.

The pump 1550 may be installed downstream of the blocking member 1540. The pump 1550 may provide exhaust pressure to the fifth exhaust line 1500.

The exhaust fluid introduced into the fifth exhaust line 1500 from the third exhaust line 1300 may flow into the sixth exhaust line 1600.

The sixth exhaust line 1600 may be connected to the fourth exhaust line 1400 and the

fifth exhaust line 1500. The sixth exhaust line 1600 may receive the exhaust fluid from the fourth exhaust line 1400 and the fifth exhaust line 1500.

A blocking member 1610 may be installed in the sixth exhaust line 1600. The blocking member 1610 may block the exhaust fluid from flowing into the sixth exhaust line 1600 based on preset conditions.

The exhaust fluid introduced into the sixth exhaust line 1600 from the fourth exhaust line 1400 and the fifth exhaust line 1500 may flow to the exhaust manifold 1700.

The exhaust manifold 1700 may be connected to the sixth exhaust line 1600. The exhaust manifold 1700 may be flowed with the exhaust fluid from the sixth exhaust line 1600. The exhaust fluid flowing from the sixth exhaust line 1600 into the exhaust manifold 1700 may be discharged to the outside.

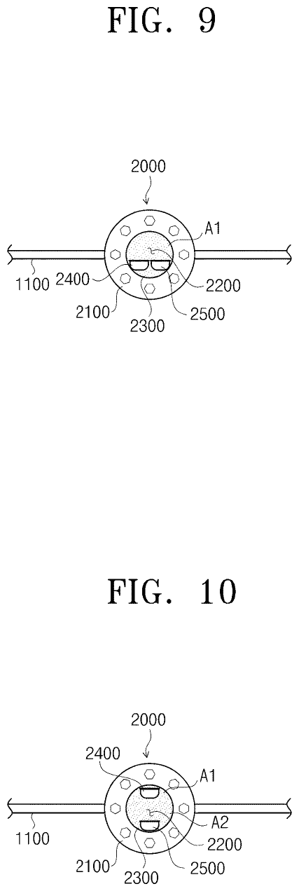

FIG. 8 is a diagram illustrating a monitoring member according to another embodiment of the present invention. FIGS. 9 and 10 are diagrams illustrating a monitoring member according to another embodiment of the present invention.

Referring to FIG. 8, a monitoring member 2000 according to another embodiment of the present invention may include a bracket 2100 that is connected to the first exhaust line 1100 and forms a hole 2200 therein, a cover 2300 that surrounds the hole 2200, and a first buoy 2400 and a second buoy 2500 provided in the hole 2300. The monitoring member 2000 may be configured the same as the monitoring member 1130 described in FIGS. 4 to 7, except that it includes two buoys (first buoy 2400 and second buoy 2500). The first buoy 2400 may have a density between the density of the drying fluid and the density of the cleaning fluid. The second buoy 2500 may have a density greater than the density of the cleaning fluid.

Referring to FIG. 9, when the exhaust fluid containing only the drying fluid flows through the first exhaust line 1100 (i.e., when only the drying fluid flows through the hole 2200), the first buoy 2400 and the second buoy 2500, which have a density greater than the density of the drying fluid, may sink.

Referring to FIG. 10, when an exhaust fluid containing a drying fluid A1 and a cleaning fluid A2 flows through the first exhaust line 1100 (i.e., the drying fluid A1 flows in the upper portion of the hole 2200 and the cleaning fluid A2 flows in the lower portion), the first buoy 2400 having a density between the density of the drying fluid A1 and the cleaning fluid A2 may float on the cleaning fluid A2, and the second buoy 2500 having a density greater than the density of the cleaning fluid A2 may sink.

The foregoing detailed description illustrates the present invention. In addition, the foregoing is intended to describe exemplary or various exemplary embodiments for implementing the technical spirit of the present invention, and the present invention may be used in various other combinations, changes, and environments. That is, the foregoing content may be modified or corrected within the scope of the concept of the invention disclosed in the present specification, the scope equivalent to that of the invention, and/or the scope of the skill or knowledge in the art. Accordingly, the detailed description of the invention above is not intended to limit the invention to the disclosed exemplary embodiment. Further, the appended claims may be construed to include other exemplary embodiments. Such modified exemplary embodiments should not be separately understood from the technical spirit or prospects of the present invention.

What is claimed is:

1. An apparatus for treating a substrate, the apparatus comprising:
a housing having a treatment space in which a substrate is placed;
a fluid supply unit for supplying a drying fluid to the treatment space; and
an exhaust unit for exhausting an exhaust fluid from the treatment space,
wherein the exhaust fluid includes at least one of the drying fluid and a cleaning fluid supplied onto the substrate and introduced into the treatment space,
wherein the exhaust unit includes:
an exhaust line connected with the housing; and
a monitoring member installed on the exhaust line,
wherein the monitoring member includes a buoy having a density between a density of the drying fluid and a density of the cleaning fluid.

2. The apparatus of claim 1, wherein the drying fluid includes carbon dioxide, and
the cleaning fluid includes isopropyl alcohol (IPA).

3. The apparatus of claim 1, wherein the exhaust unit includes:
a temperature sensor installed on the exhaust line and for measuring a temperature of the drying fluid flowing in the exhaust line; and
a pressure sensor installed on the exhaust line and for measuring a pressure of the drying fluid flowing in the exhaust line.

4. The apparatus of claim 3, wherein the monitoring member is installed between the temperature sensor and the pressure sensor.

5. The apparatus of claim 1, wherein the monitoring member includes:
a bracket connected to the exhaust line to form a hole therein; and
a cover enclosing the hole.

6. The apparatus of claim 5, wherein the cover is provided as a window.

7. The apparatus of claim 5, wherein the buoy is provided in the hole.

8. The apparatus of claim 1, wherein the exhaust fluid is a supercritical fluid.

9. An apparatus for treating a substrate, the apparatus comprising:
a housing having a treatment space in which a substrate is placed;
a fluid supply unit for supplying a drying fluid to the treatment space; and
an exhaust unit for exhausting an exhaust fluid from the treatment space,
wherein the exhaust fluid includes at least one of the drying fluid and a cleaning fluid supplied onto the substrate and introduced into the treatment space,
the exhaust unit includes:
an exhaust line connected with the housing; and
a monitoring member installed on the exhaust line,
wherein the monitoring member includes a first buoy having a density between a density of the drying fluid and a density of the cleaning fluid, and a second buoy having a density greater than the density of the cleaning fluid.

10. The apparatus of claim 9, wherein the drying fluid includes carbon dioxide, and
the cleaning fluid includes isopropyl alcohol (IPA).

11. The apparatus of claim 9, wherein the exhaust unit includes:
a temperature sensor installed on the exhaust line and for measuring a temperature of the drying fluid flowing in the exhaust line; and
a pressure sensor installed on the exhaust line and for measuring a pressure of the drying fluid flowing in the exhaust line,
wherein the monitoring member is installed between the temperature sensor and the pressure sensor.

12. The apparatus of claim 9, wherein the monitoring member includes:
a bracket connected to the exhaust line to form a hole therein; and
a cover enclosing the hole,
wherein the cover is provided as a window.

13. The apparatus of claim 12, wherein the first buoy and the second buoy are provided in the hall.

14. The apparatus of claim 9, wherein the exhaust fluid is a supercritical fluid.

15. The apparatus of claim 9, wherein the housing is a drying chamber.

16. An apparatus for treating a substrate, the apparatus comprising:
a housing having a treatment space in which a substrate is placed;
a fluid supply unit for supplying a drying fluid to the treatment space; and
an exhaust unit for exhausting an exhaust fluid from the treatment space,
wherein the exhaust fluid includes at least one of the drying fluid and a cleaning fluid supplied onto the substrate and introduced into the treatment space,
the exhaust unit includes:
an exhaust line connected with the housing;
a temperature sensor installed on the exhaust line and for measuring a temperature of the dry fluid flowing in the exhaust line;
a pressure sensor installed on the exhaust line and for measuring a pressure of the drying fluid flowing in the exhaust line; and
a monitoring member installed between the temperature sensor and the pressure sensor,
wherein the monitoring member includes a first buoy having a density between a density of the drying fluid and a density of the cleaning fluid.

17. The apparatus of claim 16, wherein the drying fluid includes carbon dioxide, and
the cleaning fluid includes isopropyl alcohol (IPA).

18. The apparatus of claim 16, wherein the monitoring member further includes a second buoy having a density greater than the density of the cleaning fluid.

19. The apparatus of claim 16, wherein the monitoring member includes:
a bracket connected to the exhaust line to form a hole therein; and
a cover enclosing the hole,
wherein the cover is provided as a window,
wherein the first buoy is provided in the hole.

20. The apparatus of claim 16, wherein the exhaust fluid is a supercritical fluid.
